(19) United States
(12) Patent Application Publication
(10) Pub. No.: US 2013/0022913 A1
(43) Pub. Date: Jan. 24, 2013

(54) METHOD FOR PRODUCING POSITIVE-TYPE PHOTOSENSITIVE RESIN COMPOSITION, POSITIVE-TYPE PHOTOSENSITIVE RESIN COMPOSITION, AND FILTER

(71) Applicants: Yuma Tanaka, Tokyo (JP); Makoto Horii, Tokyo (JP)

(72) Inventors: Yuma Tanaka, Tokyo (JP); Makoto Horii, Tokyo (JP)

(73) Assignee: SUMITOMO BAKELITE CO., LTD., Tokyo (JP)

(21) Appl. No.: 13/638,033

(22) PCT Filed: Mar. 25, 2011
(86) PCT No.: PCT/JP2011/001766

§ 371 Date: Sep. 28, 2012

(30) Foreign Application Priority Data
Mar. 31, 2010 (JP) 2010-082589

(51) Int. Cl. G03F 7/004; B01D 35/02

(52) U.S. Cl. 430/270.1; 210/348

(57) ABSTRACT

A method for producing a positive-type photosensitive resin composition which includes a process of filtering the positive-type photosensitive resin composition containing a surfactant by using a filter, wherein a contact angle on one surface of the filter is equal to or more than 30 degrees and equal to or less than 80 degrees when measured using formamide.

### TECHNICAL FIELD

The present invention relates to a method for producing a positive-type photosensitive resin composition, a positive-type photosensitive resin composition, and a filter.

### BACKGROUND ART

In the related art, a positive-type photosensitive resin composition has been widely used in the process of manufacturing an integrated circuit and a printed circuit board. As the positive-type photosensitive resin composition, for example, the combination of a polybenzoxazole resin, a polyimide resin or the like with a diazoquinone compound as the photosensitive agent has been used (For example, refer to Patent Document 1).

In addition, in order to improve the storage stability, a technique for removing particulates (dust and foreign matter such as fine particles) in the positive-type photosensitive resin composition is disclosed in Patent Document 2. The removal method includes filtering the positive-type photosensitive resin composition using a Teflon (registered trade mark) filter or a polyethylene filter (Example 1 in Patent Document 2). In the document, it is also disclosed that a surfactant may be added in order to improve the coating properties of such a positive-type photosensitive resin composition (paragraph 0032 in Patent Document 2).

### CITATION LIST

Patent Literature

[Patent Document 1] Japanese Laid-Open Patent Publication No. S56-27140 [Patent Document 2] Japanese Laid-Open Patent Publication No. 2000-256415

### SUMMARY OF INVENTION

### Technical Problem

However, the present inventors have examined and found that in a filtration process of the related art not only particulates including dust and fine particles, but also a surfactant is removed from the positive-type photosensitive resin composition. The amount of the surfactant included in the positive-type photosensitive resin composition after the filtration process in the related art becomes lower than the desired value. As a result, the wettability of the positive-type photosensitive resin composition is lowered, so that the coating properties thereof may deteriorate.

The present invention includes the following:

[1] A method for producing a positive-type photosensitive resin composition, which includes a process of filtering a positive-type photosensitive resin composition containing a surfactant by using a filter, wherein a contact angle on one surface of the filter is equal to or more than 30 degrees and equal to or less than 80 degrees, when measured using formamide;
[2] The method for producing a positive-type photosensitive resin composition described in [1], wherein the filter is a polyethylene filter;
[3] The method for producing a positive-type photosensitive resin composition described in [1] or [2], which further includes, before or after the filtration process using the filter, a process of filtering the positive-type photosensitive resin composition by using a polyamide-based filter;
[4] The method for producing a positive-type photosensitive resin composition described in [3], wherein a contact angle on one surface of the polyamide-based filter is equal to or less than 10 degrees when measured using formamide;
[5] The method for producing a positive-type photosensitive resin composition described in any one of [1] to [4], wherein the positive-type photosensitive resin composition containing the surfactant further contains at least an alkali soluble resin, a photoacid generator and a solvent;
[6] The method for producing a positive-type photosensitive resin composition described in any one of [1] to [5], wherein the surfactant is a fluorine-based surfactant;
[7] The method for producing a positive-type photosensitive resin composition described in any one of [1] to [5], wherein the surfactant includes a perfluoroalkyl group;
[8] The method for producing a positive-type photosensitive resin composition described in any one of [1] to [7], wherein a contact angle on one surface of the filter is equal to or more than 30 degrees and equal to or less than 80 degrees when measured using any of formamide, ethylene glycol and pure water;
[9] The method for producing a positive-type photosensitive resin composition described in any one of [1] to [8], wherein an average pore diameter of the filter is equal to or more than 0.05 μm and equal to or less than 0.2 μm;
[10] A positive-type photosensitive resin composition, which is obtained by the method for producing a positive-type photosensitive resin composition described in any one of [1] to [9], wherein a content of the surfactant is equal to or more than 200 ppm;
[11] A positive-type photosensitive resin composition, which is obtained by the method for producing a positive-type photosensitive resin composition described in any one of [1] to [9], wherein a number of particulates measured by a laser surface inspection device is equal to or less than 100 pcs; and
[12] A filter, which is used in a method for producing a positive-type photosensitive resin composition containing a surfactant, wherein a contact angle on one surface of the filter is equal to or more than 30 degrees and equal to or less than 80 degrees when measured using formamide.

### Advantageous Effects of Invention

According to the present invention, it is possible to provide a method for producing a positive-type photosensitive resin composition with excellent coating properties.

### DESCRIPTION OF EMBODIMENTS

Hereinafter an outline of the present invention is described.

A method for producing a positive-type photosensitive resin composition of the present invention includes a process of filtering a positive-type photosensitive resin composition containing a surfactant by using a filter. The filter is specified by a contact angle on one surface of the filter being equal to or more than 30 degrees and equal to or less than 80 degrees when measured using formamide.

Hitherto, when there are particulates including dust and foreign matter in a positive-type photosensitive resin composition, particulate-derived development defects may occur when forming a pattern. In order to suppress these development defects, a filtration process is employed in the process of producing a positive-type photosensitive resin composition of the related art so as to remove particulates by the filtration process. The filtration process of the related art employs, for example, a Teflon (registered trade mark) filter or a polyethylene filter (hereinafter referred to as a polyethylene filter of the related art, or the like). In such a filtration process of the related art, the purpose has been the removal of particulates including dust and foreign matter.

However, the present inventors have examined and found that with a polyethylene filter or the like of the related art, firstly a surfactant is removed when removing particulates including dust and foreign matter, and secondly the surfactant is also removed when removing bubbles.

Therefore, the surfactant in a positive-type photosensitive resin composition is adsorbed when a polyethylene filter of the related art or the like is used in the filtration process. As a result, the concentration of the surfactant is lowered. Accordingly, surface tension of the positive-type photosensitive resin composition is increased, the wettability with respect to a workpiece to be coated such as a silicon wafer deteriorates, and thus the ability to fill gaps deteriorates thereby causing air entrainment. As a result, defects such as cracks (deterioration of coating properties) may occur.

Accordingly, the present inventors have further examined and found that by appropriately controlling the critical surface tension of a filter for use in the filtration process, it is possible to realize filter properties in which particulates due to bubbles are adsorbed while not adsorbing the surfactant.

On the basis of the experimental results above, the inventors formulated the following hypotheses:

(i) An object passing through a filter has increased affinity with the filter when its surface tension is close to the critical surface tension of the filter and tends to be easily adsorbed on the filter. The surface tension of the object varies depending on the material. It is possible to remove only a desired object by using a filter having a critical surface tension adapted to the specific surface tension of the material;

(ii) The respective surface tensions of a surfactant and a bubble are different. Therefore, if the critical surface tension of the filter is made different from the surface tension of the surfactant, and controlled to adopt the surface tension of the bubble, the bubble alone can be adsorbed without adsorbing the surfactant;

(iii) It is possible to evaluate the critical surface tension of the filter exhibiting the properties of (ii) by the contact angle;

(iv) There is a measurement reference material with which the contact angle may be evaluated qualitatively.

The inventors have investigated, based on the hypotheses (i) to (iv) above, and found that by appropriately controlling the material of the filter and the production method, it is possible to obtain a filter that realizes the above-mentioned filter properties and to evaluate the filter properties qualitatively by the contact angle.

The detailed mechanism of how the filter properties of the present invention are realized is considered to be as follows. An object passing through a filter has increased affinity with the filter when its surface tension is close to the critical surface tension of the filter and tends to be easily adsorbed on the filter. There are three regions showing the following characteristics as the critical surface tension of the filter becomes higher. (Low interfacial tension) The first region shows high affinity with surfactant but low affinity with bubbles. (Balanced interfacial tension) The second region shows high affinity with bubbles but not high affinity with surfactant. (High interfacial tension) The third region shows low affinity with surfactant and also low affinity with bubbles. Thus, the filter having the interfacial tension of the first region has high surfactant adsorption properties and low bubble adsorption properties. The filter having the interfacial tension of the third region has low surfactant adsorption properties and also low bubble adsorption properties. In contrast, it is possible for the filter having the interfacial tension of the second region to exhibit low surfactant adsorption properties and high bubble adsorption properties.

In this way, it is considered that by appropriately controlling critical surface tension of the filter of the present invention, it is possible to realize filter properties where the filter adsorbs particulates due to bubbles while the filter does not adsorb the surfactant.

Further, it is found that the filter having interfacial tension of the second region corresponds to a filter having a contact angle of equal to or more than 30 degrees and equal to or less than 80 degrees where formamide is used.

The contact angle of the filter is preferably specified by a measurement using formamide. Formamide is a measurement reference material generally used in the measurement of the contact angle. Other than formamide, ethylene glycol and pure water are used as measurement reference materials. The surface tensions of ethylene glycol, formamide and pure water are 47.7 mN/m, 58.2 mN/m and 72.8 mN/m respectively. It has been discovered that the contact angle of the filter falls within the range of equal to or more than 30 degrees and equal to or less than 80 degrees when measured with any of the above liquids of varied surface tension, and that it is possible to obtain a result that any filter exhibits the filter properties of the present invention. Therefore, in the present invention, it is possible to specify the contact angle of the filter using the three measurement reference materials of ethylene glycol, formamide, and pure water, but as a representative of these liquids, formamide having a substantially intermediate surface tension, is preferably used. Hereinafter, ‘to measure a contact angle using a liquid having a surface tension of equal to or more than 45 mN/m and equal to or less than 75 mN/m’ means to measure the contact angle using the three liquids of ethylene glycol, formamide and pure water.

Accordingly, the present inventors have found that by using the contact angle of the filter as a reference representing critical surface tension on one surface of the filter, and appropriately controlling the contact angle to be equal to or more than 30 degrees and equal to or less than 80 degrees, it is possible to realize filter properties where the particulates due to bubbles are adsorbed while not adsorbing the surfactant, and thus completed the present invention.

In the present invention, the contact angle of the filter is preferably equal to or more than 30 degrees and equal to or less than 80 degrees, and more preferably equal to or more than 40 degrees and equal to or less than 70 degrees. The contact angle may be set in the above-mentioned range by appropriately controlling the material and the production method. By setting the contact angle of the filter to be equal to or more than a lower limit value, it is possible to suppress the surfactant that is adsorbed by the filter; and by setting it to be equal to or less than an upper limit value, it is possible to sufficiently remove bubbles and reduce the development defects of a positive-type photosensitive resin composition.

Next, methods for producing the positive-type photosensitive resin composition according to the present invention are described in detail.

First, (A) alkali soluble resin, (B) photoacid generator and (C) surfactant are dissolved in (D) solvent to obtain the positive-type photosensitive resin composition including surfactant. The positive-type photosensitive resin composition including surfactant is filtered using a filter (process (1)).

In the present invention, it is preferable to use a polyethylene filter (F1) as the filter. Other than the filter (F1), a hydrophilic Poly Tetra Fluoro Ethylene (PTFE) filter, a hollow fiber filter made of hydrophilic polypropylene and the like are examples of the filter. As the polyethylene filter, for example, there are Microgard DI (manufactured by Nihon Entegris K.K.), Microgard DEV (manufactured by Nihon Entegris K.K.) and the like.

The polyethylene filter (Fl) used in the present invention, for example, preferably has a contact angle of equal to or more than 30 degrees and equal to or less than 80 degrees with regard to the liquid having a surface tension of equal to or more than 45 mN/m and equal to or less than 75 mN/m.

As the polyethylene filter (F1), it is preferable to use a polyethylene film with a surface which is modified to be hydrophilic by, for example, being immersed in hydrophilic liquid containing polyethylene glycol, polyethylene glycol divinyl ether, polyolefin, polyacrylate, polyamide, poly-N-vinyl pyrrolidone, polysiloxane, polyoxazoline, polystyrene and the like, or by energy beam irradiation such as excimer laser irradiation, plasma irradiation and an electron beam.

Here, the contact angle of the polyethylene filter (F1) and the liquid having a surface tension of equal to or more than 45 mN/m and equal to or less than 75 mN/m means the contact angle of the polyethylene filter (F1) and the liquid having a surface tension of equal to or more than 45 mN/m and equal to or less than 75 mN/m measured after dropping 2 μl of a liquid having a surface tension of equal to or more than 45 mN/m and equal to or less than 75 mN/m on the polyethylene filter (F1) and leaving it for 10 seconds at 23° C.

The liquids having a surface tension of equal to or more than 45 mN/m and equal to or less than 75 mN/m are ethylene glycol (47.7 mN/m), formamide (58.2 mN/m) and pure water (72.8 mN/m). It is preferable that the contact angle of the polyethylene filter (F1) be equal to or more than 30 degrees and equal to or less than 80 degrees when measured with any of ethylene glycol, formamide and pure water.

The form of the polyethylene filter (F1) is not particularly limited but it is preferable to use a cartridge-type filter in terms of usability and environmental considerations.

The form of the polyethylene filter (F1) is not particularly limited, and for example, maybe in the form of a film. In addition, it is preferable that the polyethylene filter (F1), for example, includes a porous body and continuous pores are formed from a top surface to a bottom surface therein.

The average value of filter pore diameters of the polyethylene filter (F1) (hereinafter, referred to as an average pore diameter) is preferably equal to or more than 0.05 μm and equal to or less than 0.2 μm, and more preferably equal to or more than 0.1 μm and equal to or less than 0.2 μm. By setting the pore diameter to be equal to or more than the lower limit value, it is possible to improve productivity in the filtration process, and on the other hand, by setting it to be equal to or less than the upper limit value, it is possible to remove the particulates to a sufficient degree. The average pore diameter is obtained by calculation with bubble point measurement and differential pressure measurement. Bubble point measurement is a method used to calculate filter pore diameters with the value of pressure (bubble point pressure) where a bubble was generated for the first time from a pore of the largest diameter while the air pressure is gradually increased from the lower side after immersing the filter into a liquid.

According to the present invention, by using such a polyethylene filter (F1) in filtering a positive-type photosensitive resin composition, it is possible to remove particulates such as foreign matter and bubbles sufficiently while suppressing the surfactant to be adsorbed to the filter. Therefore, it is possible to realize the positive-type photosensitive resin composition with which defects such as cracks are reduced and development defects may also be greatly reduced, with excellent coating properties and an excellent yield rate.

In addition, there may be a process (II) where the positive-type photosensitive resin composition is filtered by using a polyamide-based filter (F2) before or after the filtration process by the filter (I). In particular, it is preferable to carry out the filtration process by the filter (I) after carrying out filtration by the polyamide-based filter (F2).

Examples of the polyamide-based filter (F2) used in the filtration process (II) include a filter made of nylon 6 or nylon 66. Further, one surface of the polyamide-based filter (F2) preferably has a contact angle of equal to or less than 10 degrees when measured using a liquid having a surface tension of equal to or more than 45 mN/m and equal to or less than 75 mN/m, and more preferably has a contact angle of equal to or less than 10 degrees when measured using only formamide. The upper limit value of the contact angle of the polyamide-based filter is preferably equal to or less than 10 degrees, more preferably equal to or less than 5 degrees, and on the other hand, the lower limit value is not particularly limited, but preferably equal to or more than 0 degrees. The contact angle of the polyamide-based filter may be set to fall within the above-mentioned range by appropriately controlling the material and the production method. In addition, since the contact angle of the polyamide-based filter may be set to fall within the above-mentioned range so as to be less than the contact angle of the polyethylene filter, the surfactant is hardly adsorbed on the polyamide-based filter while the most of particulates may be removed. For this reason, the initial number of particulates may be reduced while controlling the successive increase in the number of particulates by using the polyethylene filter in combination as compared with a case where the polyamide-based filter is used alone, and therefore it is possible to realize a positive-type photosensitive resin composition which has excellent coating properties and suppresses the development defects.

Here, the contact angle of the polyamide-based filter (F2) and the liquid having a surface tension of equal to or more than 45 mN/m and equal to or less than 75 mN/m means the contact angle of the polyamide-based filter (F2) and the liquid having a surface tension of equal to or more than 45 mN/m and equal to or less than 75 mN/m measured after dropping 2 μl of the liquid having a surface tension of equal to or more than 45 mN/m and equal to or less than 75 mN/m on the polyamide-based filter (F2) and leaving for 10 seconds at 23° C. Three measurement reference materials which are used as liquids having a surface tension of equal to or more than 45 mN/m and equal to or less than 75 mN/m, are ethylene glycol (47.7 mN/m), formamide (58.2 mN/m) and pure water (72.8 mN/m). It is preferable that the contact angle of the polyamide-based filter (F2) be equal to or less than 10 degrees when measured with any of ethylene glycol, formamide and pure water.

The filter pore diameters of polyamide-based filter (F2) are preferably equal to or more than 0.1 μm and equal to or less than 0.2 μm. The form is not particularly limited but it is preferable to use a cartridge-type filter in terms of usability and environmental considerations.

As specific examples of the polyamide-based filter (F2), there are filters available from Sumitomo 3M Ltd., and LifeASSURE and Photoshield (manufactured by Sumitomo 3M, Ltd.), Ultipleat (manufactured by Pall Corporation) and the like can be exemplified.

Hereinafter, an example of the method for producing a positive-type photosensitive resin composition by using a production apparatus according to the present invention will be described. The production apparatus for the positive-type photosensitive resin composition according to the present invention includes a preparation vessel, a filter, an introducing pipe and a receiving portion. The preparation vessel prepares the positive-type photosensitive resin composition by dissolving (A) alkali soluble resin, (B) photoacid generator and (C) surfactant in (D) solvent. The introducing pipe connects the preparation vessel, the filter and the receiving portion. The positive-type photosensitive resin composition prepared in the preparation vessel transfers into the introducing pipe, passes through the filter and collects in the receiving portion. A plurality of the filters may be arranged in the introducing pipe. These filters may be of the same or different types.

Hereinafter, the use of the production apparatus according to the present invention will be described.

First, in the preparation vessel, (A) alkali soluble resin, (B) photoacid generator and (C) surfactant are dissolved in (D) solvent to obtain a positive-type photosensitive resin composition.

Then, the preparation vessel is pressurized with nitrogen and the positive-type photosensitive resin composition is sent to polyethylene filter (F1) through a copolymer of tetrafluoroethylene and perfluoroalkyl vinyl ether (PFA) tube (introducing pipe) for filtration and transported to a product bottle (receiving portion).

At this time, the nitrogen pressure is preferably equal to or more than 0.05 MPa and equal to or less than 0.3 MPa, more preferably equal to or more than 0.1 MPa and equal to or less than 0.2 MPa. By setting the nitrogen pressure in this range, efficiency of removing particulates is improved and production efficiency may be maintained without being deteriorated.

The polyamide-based filter (F2) may be installed before the polyethylene filter (F1) and the positive-type photosensitive resin composition from the preparation vessel may be filtered with the polyamide-based filter (F2) and the polyethylene filter (F1) in this order and the filtrate may be collected in a product bottle.

Next, the positive-type photosensitive resin composition of the present invention will be described.

The positive-type photosensitive resin composition of the present invention contains at least (A) alkali soluble resin, (B) photoacid generator, (C) surfactant and (D) solvent.

The positive-type photosensitive resin composition of the present invention contains (A) alkali soluble resin and (B) photoacid generator. Therefore, the alkali solubility of (A) alkali-soluble resin is reduced, and once exposure is performed alkali solubility of (B) photoacid generator is increased. As a result, an effect is obtained that alkali solubility of the positive-type photosensitive resin composition itself is increased.

In addition, by performing selective exposure, alkali-solubility is decreased in an unexposed portion whereas alkali-solubility is increased in an exposed portion. Therefore, a positive-type pattern may be obtained by alkali development.

An additive such as a leveling agent, a silane coupling agent, a titanate-based coupling agent may be added to the positive-type photosensitive resin composition as necessary.

The (A) alkali-soluble resin used in the present invention is not particularly limited, and examples include a cresol novolak resin, a hydroxystyrene resin, an acrylic resin such as a methacrylate resin and a methacrylic acid ester, a cyclic olefin resins having a hydroxyl group, a carboxyl group or the like, a polyamide-based resin and the like.

Among these, the polyamide-based resin is preferred. Specifically, there are a resin having at least one of a polybenzoxazole structure and a polyimide structure and having a hydroxyl group, a carboxyl group, an ether group or an ester group on a main chain or a side chain, a resin having a polybenzoxazole precursor structure, a resin having a polyimide precursor structure, a resin having a polyamide acid ester structure, and the like.

As such a polyamide-based resin, for example polyamide-based resin represented by the following formula (1) can be exemplified.

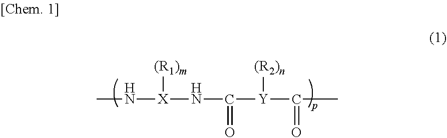

In general formula (1), X represents a cyclic compound group. R₁ is a hydroxyl group or —O—R₃, m is an integer of 0 to 2 and these may be the same or different.

Y represents a cyclic compound group. R₂ is a hydroxyl group, a carboxyl group, —O—R₃ or —COO—R₃, n is an integer of 0 to 4 and these may be the same or different. Here, R₃ is an organic group with a carbon number of 1 to 15.

Meanwhile, it is preferable that when there is no hydroxyl group as R₁, at least one of R₂ be a carboxyl group. In addition, it is preferable that when there is no carboxyl group as R₂, at least one R₁ be a hydroxyl group. p is an integer of 2 to 300.

Here, the cyclic compound group is, for example, an aromatic compound such as a benzene ring and a naphthalene ring, or a heterocyclic compound such as bisphenols, pyrroles and furans.

The polyamide-based resin represented by the general formula (1) may be obtained by, for example, reacting a compound selected from diamine, bis(aminophenol) or diaminophenol and the like with the X structure, with a compound selected from tetracarboxylic acid anhydride, trimellitic anhydride, dicarboxylic acid or dicarboxylic acid dichloride, dicarboxylic acid derivatives, hydroxydicarboxylic acid, hydroxydicarboxylic acid derivatives, and the like with Y structure. In addition, in a case where dicarboxylic acid is used, to enhance the reaction yield, an active ester type of dicarboxylic acid derivative in which 1-hydroxy-1,2,3-benzotriazole is reacted in advance may be used.

The polyamide resin represented by the general formula (1) above is anhydrated and cyclized when being heated at, for example, 300 to 400° C. and a heat-resistant resin form is obtained as a polyimide, polybenzoxazole, or a copolymer of the two.

The (B) photoacid generator used in the present invention is not limited as long as it is a compound including quinonediazide.

More specifically, 1,2-benzoquinone diazido-4-sulfonic acid ester, 1,2-naphthoquinone diazido-4-sulfonic acid ester, 1,2-naphthoquinone diazido-5-sulfonic acid ester and the like can be exemplified.

The (C) surfactant used in the present invention preferably has a function as a surfactant.

As the (C) surfactant, for example, there are nonionic surfactants such as polyoxyethylene alkyl ethers such as polyoxyethylene lauryl ether, polyoxyethylene stearyl ether and polyoxyethylene oleyl ether, polyoxyethylene aryl ethers such as polyoxyethylene octylphenyl ether and polyoxyethylene nonylphenyl ether, and polyoxyethylene dialkyl ethers such as polyoxyethylene dilaurate and polyoxyethylene distearate; commercially available fluorine-based surfactants such as Eftop 301, 303 and 352 (manufactured by Shin Akita Kasei K.K.), MEGAFACE F171, F172, F173, F177, F444, F470, F471, F475, F482and F477 (manufactured by DIC

Corporation), Fluorad FC430, Fluorad FC431, Novec FC4430 and Novec FC4432 (manufactured by Sumitomo 3M Ltd.), Surflon S-381, S-382, S-383, S-393, SC-101, SC-102, SC-103, SC-104, SC-105 and SC-106 (manufactured by AGC Seimi Chemical Co., Ltd.); organosiloxane polymer KP341 (manufactured by Shin-Etsu Chemical Co., Ltd.); (meth)acrylic copolymer Polyflow No.57 and 95 (manufactured by Kyoeisha Chemical Co., Ltd.) and the like. Among these surfactants, fluorine-based surfactants are preferable.

Among fluorine-based surfactants, a surfactant containing a perfluoroalkyl group is effective and more preferable. In such a way that surface tension is lowered by containing fluorine atoms for example, it is possible to appropriately control the surface tension of the (C) surfactant by a constituent atom or a substituent.

Specific examples of the surfactant include MEGAFACE F171, F173, F444, F470, F471, F475, F482 and F477 (manufactured by DIC Corporation) Surflon S-381, S-383 and S-393 (manufactured by AGC Seimi Chemical Co. , Ltd) , Novec FC 4430 and FC 4432 (manufactured by Sumitomo 3M, ltd.) and the like.

As the (D) solvent used in the present invention, a solvent which has excellent solubility to the (A) alkali soluble resin may be used.

Examples include N-methyl-2-pyrrolidone, γ-butyrolactone, N,N-dimethylacetamide, dimethyl sulfoxide, diethylene glycol dimethyl ether, diethylene glycol diethyl ether, diethylene glycol dibutyl ether, propylene glycol monomethyl ether, dipropylene glycol monomethyl ether, propylene glycol monomethyl ether acetate, methyl lactate, ethyl lactate, butyl lactate, methyl-1,3-butylene glycol acetate, 1,3-butylene glycol-3-monomethyl ether, methyl pyruvate, ethyl pyruvate, methyl-3-methoxypropionate and the like, and these may be used alone or in combination thereof.

The positive-type photosensitive resin composition of the present invention may contain other additives such as a leveling agent, a silane coupling agent and the like as necessary.

In the positive-type photosensitive resin composition of the present invention, the content of the surfactant is preferably equal to or more than 200 ppm and equal to or less than 1000 ppm, and more preferably equal to or more than 250 ppm and equal to or less than 500 ppm. By setting the content of the surfactant in the above-mentioned range, it is possible to obtain a sufficient surfactant effect and the positive-type photosensitive resin composition with excellent coating properties.

In addition, the positive-type photosensitive resin composition of the present invention is a positive-type photosensitive resin composition where the number of particulates measured by a laser surface inspection device is preferably equal to or more than 0 pcs and equal to or less than 100 pcs, and more preferably equal to or more than 0 pcs and equal to or less than 50 pcs. The number of particulates is measured after standing the filtered positive-type photosensitive resin composition for 3 days at 23° C. By setting the number of particulates in the above-mentioned range, it is possible to greatly reduce development defects and to realize a positive-type photosensitive resin composition with an excellent yield rate.

### EXAMPLES

Hereinafter, the present invention is described specifically with examples and comparative examples, but the present invention is not limited thereto.

### Example 1

<Measurement of Contact angle on Filter>

Liquids having the surface tensions below were prepared.

A: ethylene glycol (47.7 mN/m)

B: formamide (58.2 mN/m)

C: pure water (72.8 mN/m)

Filters with a pore diameter of 0.5 μm or less were prepared.

V: polyethylene filter V (Microgard DI manufactured by Nihon Entegris K.K., the contact angle was equal to or more than 30 degrees and equal to or less than 80 degrees with respect to a liquid having a surface tension of equal to or more than 45 mN/m and equal to or less than 75 mN/m)

W: polyethylene filter W (Microgard DEV manufactured by Nihon Entegris K.K., the contact angle was equal to or more than 30 degrees and equal to or less than 80 degrees with respect to a liquid having a surface tension of equal to or more than 45 mN/m and equal to or less than 75 mN/m)

X: Nylon 66 filter X (LifeASSURE EMC manufactured by Sumitomo 3M, ltd., the contact angle was 10 degrees or less with respect to a liquid having a surface tension of equal to or more than 45 mN/m and equal to or less than 75 mN/m; this is the polyamide-based filter (F2) used in the present invention.)

Y: polypropylene filter Y (PolyPro manufactured by Sumitomo 3M, ltd., the contact angle was greater than 80 degrees with respect to a liquid having a surface tension of equal to or more than 45 mN/m and equal to or less than 75 mN/m)

Z: polyethylene filter Z (Microgard UPE manufactured by Nihon Entegris K.K., the contact angle was greater than 80 degrees with respect to a liquid having a surface tension of equal to or more than 45 mN/m and equal to or less than 75 mN/m)

Each liquid was dropped by 2 μl at 23° C. on each filter, after being left 10 seconds the contact angles of the liquids were measured using a surface tension measuring device DropMaster 500 (manufactured by Kyowa Interface Science Co., ltd.).

Measurement results are shown in Table 1.

Polyethylene filter V and polyethylene filter W had a contact angle of equal to or more than 30 degrees and equal to or less than 80 degrees with respect to a liquid having a surface tension of equal to or more than 45 mN/m and equal to or less than 75 mN/m, and had good wettability.

Nylon 66 filter X had a contact angle of less than or equal to 10 degrees since wettability is excessively high.

Polyethylene filter Z and polypropylene filter Y had a contact angle of greater than 80 degrees with respect to a liquid having a surface tension of equal to or more than 45 mN/m and equal to or less than 75 mN/m (Ethylene glycol, formamide and pure water) and had low wettability.

TABLE 1

| Type of liquid | | Type of filter | | | | |
|---|---|---|---|---|---|---|
| measured | | V | W | X | Y | Z |
| A | (Degrees) | 64.2 | 67.2 | 0 | 103 | 116 |
| B | (Degrees) | 63.5 | 64.7 | 0 | 80.2 | 88.4 |
| C | (Degrees) | 47.2 | 58.4 | 0 | 88.3 | 83.4 |

The results of filtration using the positive-type photosensitive resin composition are shown in Examples 2 to 7 and Comparative Examples 1 and 2.

### Example 2

### <Synthesis of (A) Alkali-Soluble Resin>

467.9 parts by weight (0.95 mol) of dicarboxylic acid derivatives obtained by reacting 1 mol of Diphenyl ether-4,4′-dicarboxylic acid and 2 mol of 1-hydroxybenzotriazole, and 366.4 parts by weight (1 mol) of hexafluoro-2,2-bis(3-amino-4-hydroxyphenyl)propane were added to a four-necked separable flask equipped with a thermometer, a stirrer, a raw material inlet port and a dry nitrogen gas introduction tube, and 3000 parts by weight of N-methyl-2-pyrrolidone was added and dissolved. Thereafter these were reacted using an oil bath at 75° C. for 12 hours.

Next, after filtering the reaction mixture, the reaction mixture was introduced to a solution of water/isopropyl alcohol=3/1, the precipitate was collected by filtration and thoroughly washed with water, and then dried under a vacuum, to obtain a polyamide resin as (A) alkali soluble resin having a repeating unit of general formula (A-1) (a resin which is anhydrated and cyclized when heated at 300° C. to 400° C., and becomes polybenzoxazole resin).

### <Preparation of Positive-Type Photosensitive Resin Composition>

100 parts by weight of a polyamide resin having a repeating structure of the following formula (A-1), 25 parts by weight of a photoacid generator having a structure of the following formula (B-1) and 0.08 parts by weight of a surfactant containing a perfluoroalkyl group F482 (manufactured by DIC Corporation) were dissolved in 150 parts by weight of γ-butylolactone, to obtain a positive-type photosensitive resin composition A.

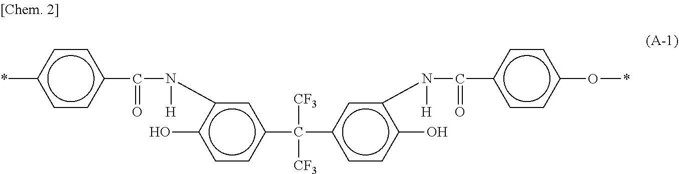

(Number of repetitions is an integer of 2 to 300)

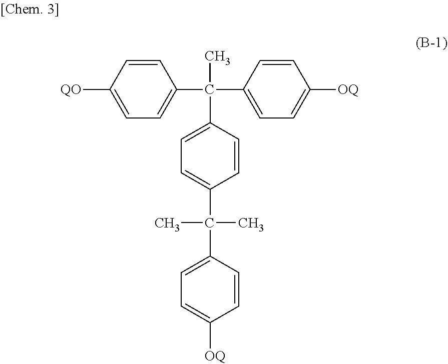

In the formula, Q represents a hydrogen atom or

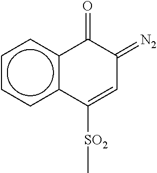

and 70% of the total of Q is

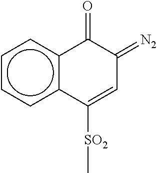

The positive-type photosensitive resin composition A was subjected to a filtration process (I) by pressurizing under nitrogen gas of 0.15 MPa, with the use of polyethylene filter V (F1) (Microgard DI manufactured by Nihon Entegris K.K.) which has the filter pore diameter of 0.1 μm and the contact angle is equal to or more than 30 degrees and equal to or less than 80 degrees with respect to a liquid having a surface tension of equal to or more than 45 mN/m and equal to or less than 75 mN/m.

The obtained filtrate of the positive-type photosensitive resin composition was applied to a wafer (a wafer with no surface step) using a spin coater and then dried on a hotplate at 120° C. for 4 minutes, to obtain a coating film A with a film thickness of approximately 7 μm.

In addition, as in the above manner, the prepared filtrate of the positive-type photosensitive resin composition was applied to the surface of a wafer with a step which is 10 μm in width and 150 μm in height using a spin coater, and then dried on a hotplate for 4 minutes, to obtain a coating film B with a film thickness of 7 μm.

### <Characteristic Evaluation>

[Surface Tension]

Regarding the positive-type photosensitive resin composition, the surface tension of the positive-type photosensitive resin composition before and after the filtration process was measured using the surface tension measuring device DropMaster 500 (manufactured by Kyowa Interface Science Co., Ltd.). As a result, the difference between the values of the surface tension before and after the filtration process was 1% or less.

### [Surfactant Amount]

In addition, the surfactant amount in the positive-type photosensitive resin composition before and after the filtration process was measured using the F-NMR measurement and this difference also was 1% or less. The F-NMR measurement is a method analyzing ¹⁹F using AVANCE 500 type manufactured by Bruker Co. After precisely weighing 0.5 g of the positive-type photosensitive resin composition, 1 ml of deuterated acetone was added thereto to dissolve completely, thereby obtaining a measuring sample. Next, the measuring sample was poured into a sample tube of F-NMR, and filled up to a height of 6 cm. The simulated liquid (200 ppm) was measured by F-NMR, the integrated value of a signal group of −125 ppm to −121 ppm was normalized, and the quantity of the surfactant component in a product was determined by one point calibration method.

### [Number of Particulates A and Number of Particulates B]

With respect to the prepared coating film A, the number of particulates A which are observed as foreign matter having a particle diameter of 0.3 μm or more was measured using a laser surface inspection apparatus LS-5000 (manufactured by Hitachi Electronics Engineering Co., Ltd.), and the result given was less than 50 pcs. In the same manner, the number of particulates B which are observed as bubbles was measured using a laser surface inspection apparatus, and the result given was less than 30 pcs.

Here, the number of particulates A which are observed as foreign matter, was set to be the number of particulates measured in the positive-type photosensitive resin composition after being left to stand at 23° C. for 3 days. The number of particulates B which are observed as bubbles was shown as the difference of the number of particulates measured in the positive-type photosensitive resin composition after being left to stand for 1 day and the number of particulates measured after leaving to stand for 3 days.

Surface observation was carried out with respect to the prepared coating film B, and there were no bubbles at a step and good coating properties were observed.

### Example 3

A nylon 66 filter X (LifeASSURE EMC, manufactured by Sumitomo 3M, ltd.) as polyamide-based filter (F2) with a pore diameter of 0.2 μm was installed before the polyethylene filter V (F1) (Microgard DI, manufactured by Nihon Entegris K.K.) where the contact angle is equal to or more than 30 degrees and equal to or less than 80 degrees with respect to a liquid having a surface tension of equal to or more than 45 mN/m and equal to or less than 75 mN/m, which was used in the filtration process (I) in Example 2. These filters were linked and the filtration process (II) was performed while carrying out pressurizing under nitrogen gas of 0.15 MPa, and an evaluation was carried out in the same manner as Example 2.

The evaluation results were that the difference between surface tension of the positive-type photosensitive resin composition before and after the filtration process [(II)+(I)] was 1% or less and the difference between the amount of surfactant before and after the filtration process [(II)+(I)] was 1% or less measured by F-NMR.

The obtained filtrate of the photosensitive resin composition was applied to a wafer (a wafer with no step on the surface) using a spin coater and dried on a hotplate at 120° C. for 4 minutes, to obtain the coating film A with a film thickness of approximately 7 μm.

With respect to the obtained coating film A, the number of particulates A having a particle diameter of 0.3 μm or more was measured using a laser surface inspection apparatus, and the result given was less than 30 pcs. In the same manner, the number of particulates B which are observed as bubbles was measured using a laser surface inspection apparatus, and the result given was less than 30 pcs.

Further, coating film B was prepared on the surface of a wafer with a step which is 10 μm in width and 150 μm in height in the same manner as the coating film A. Surface observation was carried out with respect to the prepared coating film B, and there were no bubbles at a step and good coating properties were observed.

### Example 4

Except that the surfactant F477 (manufactured by DIC Corporation) containing a perfluoroalkyl group was used instead of the surfactant F482 (manufactured by DIC Corporation) used in Example 2, the positive-type photosensitive resin composition B, the coating film A and the coating film B were prepared and the evaluation was carried out in the same manner as Example 2.

Regarding the evaluation result, the surfactant amount in the positive-type photosensitive resin composition before and after the filtration process was measured using the F-NMR measurement and this difference was 1% or less.

With respect to the coating film A, the number of particulates A having a particle diameter of 0.3 μm or more was measured using a laser surface inspection apparatus, and the result given was less than 50 pcs. In the same manner, the number of particulates A which are observed as bubbles measured using a laser surface inspection apparatus was less than 30 pcs.

Surface observation was carried out with respect to the prepared coating film B, and there were no bubbles at a step and good coating properties were observed.

### Example 5

### <Synthesis of (A) Alkali-Soluble Resin>

30.0 g (0.082 mol) of 2,2-bis (3-amino-4-hydroxyphenyl)hexafluoropropane and 400 ml of acetone were added into a 500 ml of round bottomed flask and stirred until 2,2-bis (3-amino-4-hydroxyphenyl)hexafluoropropane was dissolved. Thereto, 12.4 g (0.18 mol) of para-nitrobenzoyl chloride dissolved in 100 ml of acetone was added dropwise for 30 minutes while cooling so that the temperature is below 20° C., to obtain a mixture. After dropwise addition, the mixture was heated to 40° C., stirred for 2 hours and 30.0 g (0.218 mol) of potassium carbonate was gradually added thereto, followed by further stirring for 2 hours. Heating was stopped and the mixture was further stirred for 18 hours at room temperature. Thereafter, while the mixture was stirred vigorously, aqueous sodium hydroxide solution was gradually added thereto, and after the addition, the mixture was heated to 55° C. and stirred further for 30 minutes. After completion of stirring, the mixture was cooled to room temperature, 37 wt % of aqueous hydrochloric acid solution and 500 ml of water were added to adjust pH to be within the range 6.0 to 7.0. Thus obtained precipitate was separated by filtration, followed by washing with water and drying at a temperature between 60° C. and 70° C. to obtain solid bis-N,N′-(para-nitrobenzoyl) hexafluoro-2,2-bis (4-hydroxyphenyl) propane. 51.0 g of the obtained solid was dissolved completely by adding 316 g of acetone and 158 g of methanol, followed by heating at 50° C. Thereto, 300 ml of pure water at 50° C. was for 30 minutes followed by heating to 65° C. Thereafter, this mixture was cooled slowly to room temperature, thus precipitated crystals were filtered, and crystals were dried at 70° C. for purification, to obtain bis-N,N′-(para-nitrobenzoyl) hexafluoro-2,2-bis (4-hydroxyphenyl) propane.

20g of obtained bis-N, N′-(para-nitrobenzoyl) hexafluoro-2,2-bis (4-hydroxyphenyl) propane was added into a 1 l flask with 1.0 g of 5% palladium on carbon and 180.4 g of ethyl acetate so as to form a suspension. Hydrogen gas was purged and a reduction reaction was carried out by shaking for 35 minutes while heating at 50° C. to 55° C. After completion of the reaction, the suspension was cooled to 35° C. and nitrogen was purged. After the catalyst was removed by filtration, the solvent in the filtrate was evaporated using an evaporator. The product obtained was dried at 90° C. to obtain bis-N,N′-(para-aminobenzoyl) hexafluoro-2,2-bis (4-hydroxyphenyl) propane.

14.27 parts by weight (0.024 mol) of bis-N,N′-(para-aminoobenzoyl) hexafluoro-2,2-bis (4-hydroxyphenyl) propane and 40 parts by weight of γ-butyrolactone were added into a 300 ml flask and cooled to 15° C. under stirring. Thereto, 6.86 parts by weight (0.022 mol) of 4,4′-oxydiphthalic acid anhydride and 12.0 parts by weight of γ-butyrolactone were added and stirred at 20° C. for 1.5 hours. Thereafter, after heating to 50° C. and stirring for 3 hours, 5.27 g (0.044 mol) of N,N-dimethylformamide dimethyl acetal and 10.0 g of γ-butyrolactone were added and stirred further at 50° C. for 1 hour. After completion of the reaction, the mixture was cooled to room temperature and a polyamide resin which is (A) alkali soluble resin with a repeating unit represented by general formula (A-2) (a resin which is anhydrated and cyclized when heated at 300 to 400° C., and becomes polyimide benzoxazole resin) was obtained.

100 parts by weight of the polyamide resin having a repeating structure of the following formula (A-2), 25 parts by weight of the photoacid generator having a structure of (B-1), and 0.08 parts by weight of the surfactant F482 (manufactured by DIC Corporation) containing a perfluoroalkyl group were dissolved in 150 parts by weight of γ-butyrolactone, to obtain a positive-type photosensitive resin composition C.

Except that the positive-type photosensitive resin composition C was used instead of the positive-type photosensitive resin composition A used in Example 2, the coating film A and the coating film B were prepared and the evaluation was carried out in the same manner as Example 2.

Regarding the evaluation result, the surfactant amount in the positive-type photosensitive resin composition before and after the filtration process was measured using the F-NMR measurement and this difference was 1% or less.

With respect to the coating film A, the number of particulates A having a particle diameter of 0.3 μm or more was measured using a laser surface inspection apparatus, and the result given was less than 50 pcs. In the same manner, the number of particulates B which are observed as bubbles measured using a laser surface inspection apparatus was less than 30 pcs.

Surface observation was carried out with respect to the prepared coating film B, and there were no bubbles at a step and good coating properties were observed.

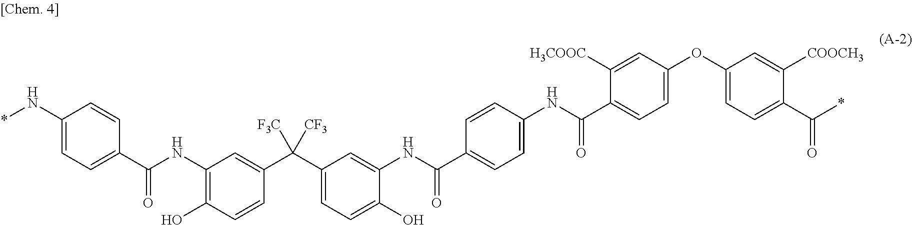

(Number of repetitions is an integer between 2 to 300.)

### Example 6

Except that the filtration process (I) was carried out by pressurizing with nitrogen gas of 0.3 MPa, the positive-type photosensitive resin composition, the coating film A and the coating film B were prepared and the evaluation was carried out in the same manner as Example 2.

Regarding the evaluation results, the difference between the values of the surface tension before and after the filtration of the positive-type photosensitive resin composition was 1% or less, the difference between the amount of surfactant before and after the filtration when measured by F-NMR was 1% or less, and the number of particulates A and number of particulates B observed were favorable.

When surface observation was carried out with respect to the prepared coating film B, there were no bubbles at a step and good coating properties were observed.

### Example 7

Except that the filtration process (I) was carried out by pressurizing with nitrogen gas of 0.05 MPa, the positive-type photosensitive resin composition, the coating film A and the coating film B were prepared and the evaluation was carried out in the same manner as Example 2.

Regarding the evaluation results, the difference between the values of the surface tension before and after the filtration of the positive-type photosensitive resin composition was 1% or less, the difference between the amount of surfactant before and after the filtration when measured by F-NMR was 1% or less, and the number of particulates A and number of particulates B observed were favorable.

When surface observation was carried out with respect to the prepared coating film B, there were no bubbles at a step and good coating properties were observed.

### Comparative Example 1

Except that the filtration process was carried out using the polyethylene filter Z (Microgard UPE, manufactured by Nihon Entegris K.K.) where the pore diameter is 0.2 μm and the contact angle is greater than 80 degrees instead of the polyethylene filter V (F1) (Microgard DI, manufactured by Nihon Entegris K.K.) used in Example 2, the positive-type photosensitive resin composition, the coating film A and the coating film B were prepared and the evaluation was carried out in the same manner as Example 2.

Regarding the evaluation results, the difference between the values of the surface tension before and after the filtration of the positive-type photosensitive resin composition was increased by 6.1%, and the difference between the amount of surfactant before and after the filtration when measured by F-NMR was decreased by 43%.

When surface observation was carried out with respect to the prepared coating film B, there were bubbles at the step due to lack of wettability and there were number of cracks due to the bubbles.

### Comparative Example 2

Except that the filtration process was carried out using the nylon 66 filter X (LifeASSURE EMC, manufactured by Sumitomo 3M, ltd.) with a pore diameter of 0.2 μm instead of the polyethylene filter V (F1) (Microgard DI, manufactured by Nihon Entegris K.K.) used in Example 2, the positive-type photosensitive resin composition, the coating film A and the coating film B were prepared and the evaluation was carried out in the same manner as Example 2.

Regarding the evaluation results, the difference between the values of the surface tension before and after the filtration of the positive-type photosensitive resin composition was 1% or less, and the difference between the amount of surfactant before and after the filtration when measured by F-NMR was also 1% or less, the number of particulates B which were observed as bubbles was 1,000 or more.

When surface observation was carried out with respect to the prepared coating film B, there were no bubbles at a step and good coating properties were observed.

TABLE 2

| | | Example 2 | | Example 3 | | Example 4 | | Example 5 | |
|---|---|---|---|---|---|---|---|---|---|
| | | Before | After | Before | After | Before | After | Before | After |
| | | filtra- | filtra- | filtra- | filtra- | filtra- | filtra- | filtra- | filtra- |
| | | tion | tion | tion | tion | tion | tion | tion | tion |
| Configuration of filter | | Nil | V | Nil | X + V | Nil | V | Nil | V |
| Filtration pressure(MPa) | | 0.15 | | 0.15 | | 0.15 | | 0.15 | |
| Photosensitive | | A | | A | | B | | C | |
| resin composition | | | | | | | | | |
| before filtration | | | | | | | | | |
| Surface tension | (mN/m) | 38.5 | 38.6 | 38.5 | 38.7 | 39 | 39.3 | 38.7 | 38.8 |
| Rate of change | (%) | 0.3 | | 0.7 | | 0.7 | | 0.3 | |
| Amount of | (ppm) | 300 | 300 | 300 | 303 | 300 | 299 | 300 | 398 |
| surfactant | | | | | | | | | |
| Rate of change | (%) | 0 | | 1 | | 0.3 | | 0.6 | |
| Number of | (pcs) | — | 33 | — | 8 | — | 28 | — | 36 |
| particulates A | | | | | | | | | |
| Number of | (pcs) | — | 9 | — | 10 | — | 9 | — | 8 |
| particulates B | | | | | | | | | |

| | | | | |
|---|---|---|---|---|
| Evaluation of coating | Good | Good | Good | Good |
| properties on step | | | | |

“—”: The number of the particulates and the bubbles were not counted as there were too many.

TABLE 3

| | | | | | | Comparative | | Comparative | |
|---|---|---|---|---|---|---|---|---|---|
| | | Example 6 | | Example 7 | | Example 1 | | Example 2 | |
| | | Before | After | Before | After | Before | After | Before | After |
| | | filtra- | filtra- | filtra- | filtra- | filtra- | filtra- | filtra- | filtra- |
| | | tion | tion | tion | tion | tion | tion | tion | tion |
| Configuration of filter | | Nil | V | Nil | V | Nil | Z | Nil | X |
| Filtration pressure(MPa) | | 0.3 | | 0.05 | | 0.15 | | 0.15 | |
| Photosensitive | | A | | A | | A | | A | |
| resin composition | | | | | | | | | |
| before filtration | | | | | | | | | |
| Surface tension | (mN/m) | 38.5 | 38.5 | 38.5 | 38.6 | 38.7 | 41.2 | 38.7 | 38.6 |
| Rate of change | (%) | 0 | | 0.3 | | 6.1 | | 0.5 | |
| Amount of | (ppm) | 300 | 300 | 300 | 301 | 300 | 170 | 300 | 303 |
| surfactant | | | | | | | | | |
| Rate of change | (%) | 0 | | 0.3 | | 43 | | 1 | |
| Number of | (pcs) | — | 42 | — | 25 | — | 6 | — | 13 |
| particulates A | | | | | | | | | |
| Number of | (pcs) | — | 15 | — | 7 | — | 8 | — | >1000 |
| particulates B | | | | | | | | | |

| | | | | |
|---|---|---|---|---|
| Evaluation of coating | Good | Good | Cracks found | Good |
| properties on step | | | | |

“—”: The number of the particulates and the bubbles were not counted as there were too many.

In this application, priority is claimed on Japanese Patent Application No 2010-082589 filed on Mar. 31, 2010, the content of which is incorporated herein by reference.

1-12. (canceled)

13. A method for producing a positive-type photosensitive resin composition, comprising:
a process of filtering a positive-type photosensitive resin composition containing a surfactant by using a filter,
wherein a contact angle on one surface of said filter is equal to or more than 30 degrees and equal to or less than 80 degrees when measured using formamide.

14. The method for producing a positive-type photosensitive resin composition according to claim 13,
wherein said filter is a polyethylene filter.

15. The method for producing a positive-type photosensitive resin composition according to claim 13, further comprising:
before or after said process of filtering process of filtering by using said filter, a process of filtering said positive-type photosensitive resin composition by a polyamide-based filter.

16. The method for producing a positive-type photosensitive resin composition according to claim 15,
wherein a contact angle on one surface of said polyamide-based filter is equal to or less than 10 degrees when measured using formamide.

17. The method for producing a positive-type photosensitive resin composition according to claim 13,
wherein said positive-type photosensitive resin composition containing said surfactant further contains at least an alkali soluble resin, a photoacid generator and a solvent.

18. The method for producing a positive-type photosensitive resin composition according to claim 13,
wherein said surfactant is a fluorine-based surfactant.

19. The method for producing a positive-type photosensitive resin composition according to claim 13,
wherein said surfactant includes a perfluoroalkyl group.

20. The method for producing a positive-type photosensitive resin composition according to claim 13,
wherein a contact angle on one surface of said filter is equal to or more than 30 degrees and equal to or less than 80 degrees when measured using any of formamide, ethylene glycol and pure water.

21. The method for producing a positive-type photosensitive resin composition according to claim 13,
wherein an average pore diameter of said filter is equal to or more than 0.05 μm and equal to or less than 0.2 μm.

22. A positive-type photosensitive resin composition, which is obtained by the method for producing a positive-type photosensitive resin composition according to claim 13,
wherein a content of said surfactant is equal to or more than 200 ppm.

23. A positive-type photosensitive resin composition, which is obtained by the method for producing a positive-type photosensitive resin composition according to claim 13,
wherein a number of particulates measured by a laser surface inspection device is equal to or less than 100 pcs.

24. A filter, which is used in a method for producing a positive-type photosensitive resin composition containing a surfactant,
wherein a contact angle on one surface of said filter is equal to or more than 30 degrees and equal to or less than 80 degrees when measured using formamide.
